(19) United States
(12) Patent Application Publication
(10) Pub. No.: US 2012/0152735 A1
(43) Pub. Date: Jun. 21, 2012

(54) Production of Nanoparticles

(75) Inventors: Lars Allers, Oxfordshire (GB); Alistair Kean, Oxfordshire (GB); Thomas Matthew Wynne-Powell, Oxford (GB)

(73) Assignee: MANTIS DEPOSITION LIMITED, Oxfordshire (GB)

(21) Appl. No.: 13/377,843

(22) PCT Filed: Jun. 30, 2010
(86) PCT No.: PCT/GB2010/001264

§ 371 Date: Mar. 5, 2012

(30) Foreign Application Priority Data
Jun. 17, 2009 (GB) 0910401.9

(51) Int. Cl. C23C 14/34

(52) U.S. Cl. 204/298.06

(57) ABSTRACT

Composite nanoparticles can be produced by a processing apparatus comprising a source of charged, moving nanoparticles or a first material and a first size, apparatus for imposing a like potential in a region lying in the path of the nanoparticles, and a physical vapour deposition source of a second material directed toward the region, thereby to produce nanoparticles of a second and greater size being a composite of the first and second materials. The apparatus for imposing a like potential can comprise one or more conductive rings surrounding the path of the nanoparticles, each at a successively lower potential. The physical vapour deposition source can be one or more of a sputter target, or an evaporative source, or another PVD source. There can be a plurality of physical vapour deposition sources, thereby allowing a larger region in which the shell is deposited. All of the physical vapour deposition sources can deposit the same material, for a uniform shell. Alternatively, different sources could allow for multiple shells or alloy shells.

### FIELD OF THE INVENTION

The present invention relates to the production of nanoparticles.

### BACKGROUND ART

Nanoparticles can be produced by a range of methods, including vacuum deposition processes. Normal deposition processes call for the material to be evaporated into a vacuum chamber and then deposited onto a substrate. To produce nanoparticles, the evaporated material can be allowed to linger in the gaseous phase to permit nucleation of nanoparticles.

### SUMMARY OF THE INVENTION

The present invention addresses the problem of creating composite nanoparticles. There is a demand for nanoparticles which comprise an inner core surrounded by an outer shell or coating, for a range of reasons. In some cases, this is because it is the surface of a nanoparticle that is effective, so where the desired material is particularly expensive (such as Platinum) it can be more cost-effective to use the expensive material only on the outer parts of the nanoparticle where it will have some effect. In other cases, a conductive or semi-conductive material can be deposited over a non-conductive core to create a nanoparticle with interesting quantum/electronic properties. In biological systems, a composite nanoparticle can be produce with different properties being shown by the core and the shell. For example, a nanoparticle with a tumour marker on the surface and a potent anti-tumour drug (such as Fe) in the core could be of greater efficacy in that the drug would only be delivered to the tumour and could hence be given at a higher dose than would otherwise be sustainable.

The evident problem lies in the production of such particles. Given that a nanoparticle might consist of a mere 50,000 atoms, this is not a straightforward task.

The present invention therefore provides an apparatus for the processing of nanoparticles, comprising a source of charged, moving nanoparticles of a first material and a first size, apparatus for imposing a like potential in a region lying in the path of the nanoparticles, and a physical vapour deposition (PVD) source of a second material directed toward the region, thereby to produce nanoparticles of a second and greater size being a composite of the first and second materials.

This works by allowing the charged nanoparticles to encounter a like electrical potential, i.e. an electrical potential that is the same sign as that of the charge on the nanoparticles. As they enter this region, they will slow and, therefore spend a greater time in that region. One or more PVD sources directed at the region will then be able to create a vapour of the intended shell material which will deposit on the slower-moving nanoparticles, increasing their size and creating the desired core/shell structure.

The apparatus for imposing a like potential can comprise one or more conductive rings surrounding the path of the nanoparticles. The like potential can decrease from a maximum to a minimum in the direction of travel of the moving nanoparticles, for example by providing a plurality of conductive rings along the path of the nanoparticles, each at a successively lower potential. This can be achieved by connecting each of the conductive rings to a neighbouring ring by an electrically resistive element, connecting a first conductive ring in the series to a voltage source, and connecting a last conductive ring to an earth. In this way, the approaching nanoparticles initially enter a region of high like potential and decelerate significantly. They then gradually move to areas of lesser like potential, and accelerate down the potential gradient until they leave the structure at approximately the same velocity with which then entered.

Generally, the moving nanoparticles will be negatively charged, so the imposed potential will be negative.

The physical vapour deposition source can be one or more of a sputter target, or an evaporative source, or another PVD source. There can be a plurality of physical vapour deposition sources, thereby allowing a larger region in which the shell is deposited. All of the physical vapour deposition sources can deposit the same material, for a uniform shell. Alternatively, different sources could allow for multiple shells or alloy shells.

### BRIEF DESCRIPTION OF THE DRAWINGS

An embodiment of the present invention will now be described by way of example with reference to the accompanying figures, in which:

FIG. 1 is a sectional view through an apparatus for producing composite nanoparticles;

FIG. 2 shows the conductive rings in more detail; and

FIG. 3 shows the variation in electrical potential with distance.

### DETAILED DESCRIPTION OF THE EMBODIMENTS

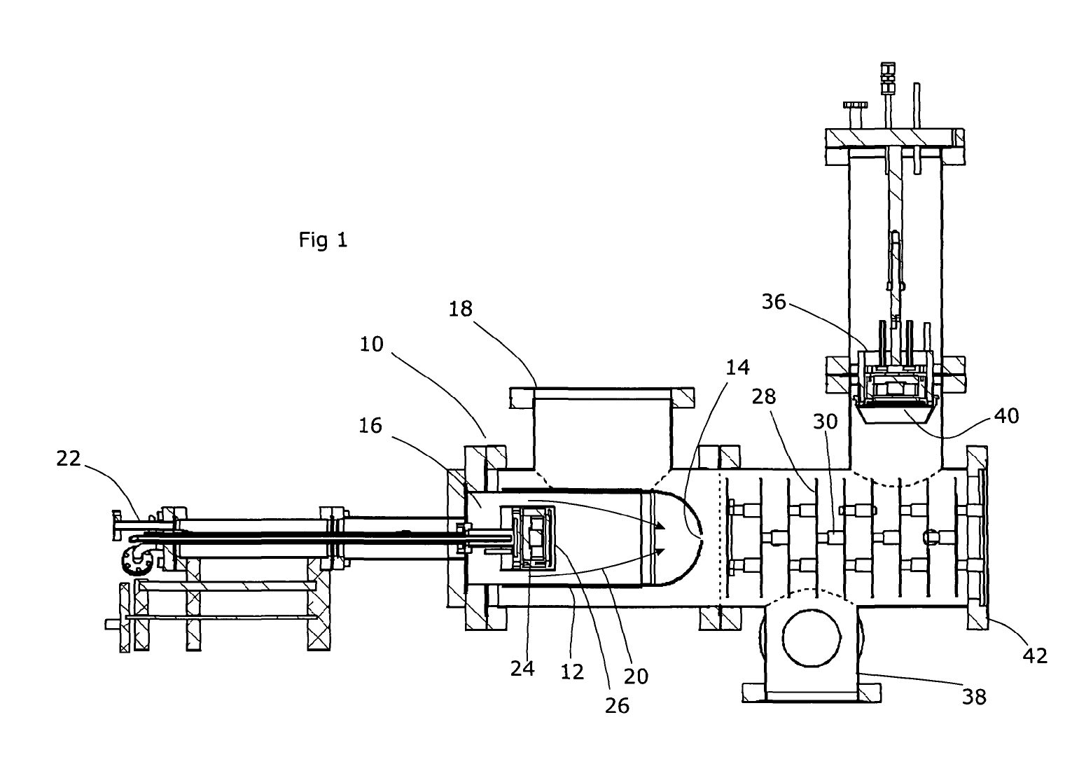

Referring to FIG. 1, an apparatus for the production of composite nanoparticles is disclosed. This consists of, on the left hand side as illustrated in FIG. 1, an apparatus 10 for producing nanoparticles. These nanoparticles will eventually form the core of the resulting composites of nanoparticles. An enclosure 12 has an outlet 14 at its right-most end and contains a gas 16 at a low pressure. This is enclosed within a vacuum chamber 18, and accordingly the low pressure gas 16 is at an elevated pressure relative to the surrounding space. As a result, the low pressure gas 16 will escape via the outlet 14, forming a flow of gas as illustrated by arrows 20. A gas inlet 22 is accordingly provided at the left-most end of the enclosure 12, in order to maintain and replenish the supply of low pressure gas 16.

A sputter deposition apparatus 24 is provided within the enclosure 12, and is generally conventional in nature. A sputter target 26 is provided, of the material intended for the core of the nanoparticles to be produced. This sputters material into the low pressure gas 16, generally toward the outlet 14. The sputtered particles become entrained in the gas flow 20 and are subjected to repeated mutual collisions by the low pressure gas 16 during the time that they remain in the flow toward the outlet 14. These collisions, over time, allow the sputtered particles to coalesce into nanoparticles in the manner that we have described previously, for example in GB2430202A, a document that is hereby incorporated by reference and to which the skilled reader is specifically referred for a full understanding of the present invention.

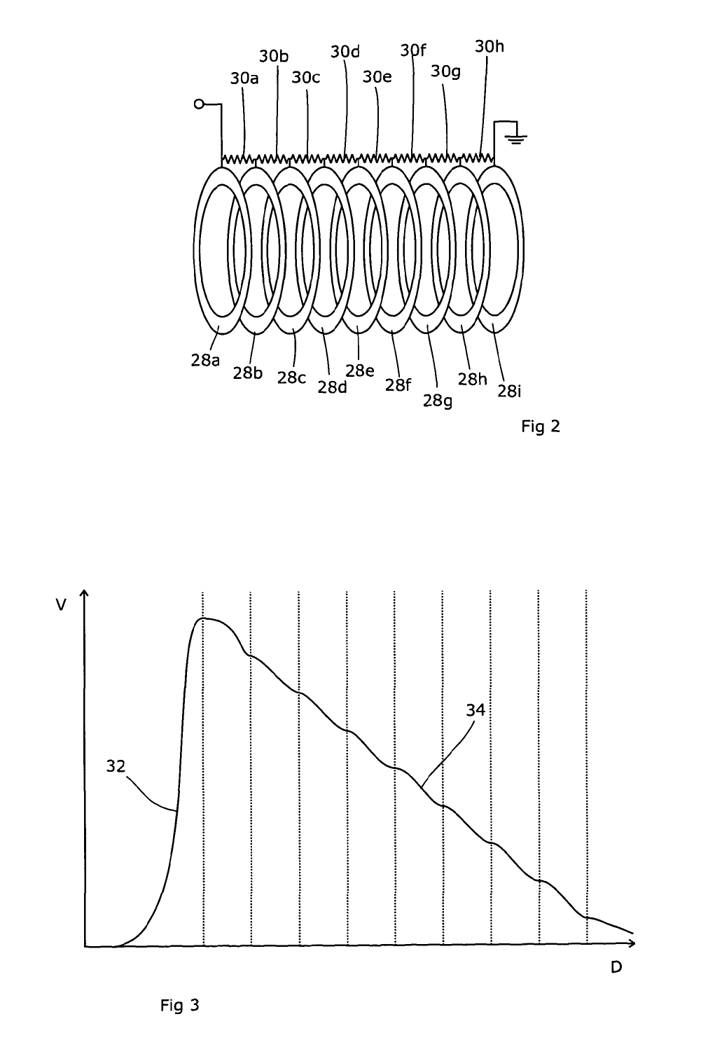

The resulting nanoparticles remain entrained in the gas flow 20 and therefore exit the enclosure 12 through the aperture 14. On exit, they pass through a series of axially spaced conductive rings 28, also shown schematically in FIG. 2. Each ring 28 is held apart by a spacer 30 (FIG. 1) which connects one ring to the next. Each spacer 30 is electrically resistive (FIG. 2), the first ring 28a is connected to an elevated negative voltage, and the last ring 28i is connected to earth. As a result, an electrical current flow from one ring to the next via the resistive spacers, causing a voltage drop to exist over each spacer. Thus, the overall effect of the series of conductive rings is to create a voltage profile as shown in FIG. 3 in which the nanoparticles, moving from left to right as in FIG. 1, initially meet a steeply increasing potential 32 (at the first ring 28a), which then decreases gradually in a generally steady slope 34. In fact, each ring is at a potential that is between the supply voltage and ground, dictated by its position along the chain of resistors 30a-30i.

As previously described in GB243020A, the nanoparticles produced by the apparatus 10 are generally negatively charged. This is the reason why the first ring is connected to an elevated negative charge. If an alternative nanoparticle production system were used which produced positively charged nanoparticles, the first ring 28a could be connected to an elevated positive potential instead. The effect of the potential hill 32 that is created in this way is to decelerate the arriving nanoparticles. The voltage of the first ring 28a is set so that this deceleration is insufficient to completely arrest (or repel) the nanoparticles, and therefore they manage to travel past the first ring 28a albeit at a lower velocity. They then meet the successively declining potential 34, which causes them to accelerate towards the last conductive ring 28i.

The last ring 28i is connected to earth, which is the same potential as that at which the nanoparticles started. Thus, the acceleration whilst within the rings 28 exactly balances the initial deceleration encountered at the first ring 28a. However, this initial deceleration followed by the slow regaining of that speed means that the nanoparticles linger in the area of the conductive rings. The varying potential created by the rings establishes a “dwell zone” within the area of those rings.

Two further sputter deposition systems are provided, on either side of the dwell zone. A first sputter deposition apparatus 36 is disposed on one side, and a second sputter deposition apparatus (not shown) is provided with access via port 38 in the vacuum system. These are provided with a second target 40 of a different material which is intended to form the shell of the number particles. Both sputter deposition systems 36 are directed towards the dwell zone and project evaporated material towards it between the conductive rings 28. Accordingly, whilst in the dwell zone, the nanoparticles are allowed to coalesce with the thus-created cloud of the second material, and the resulting nanoparticles have distinct core and shell structures. Eventually, the nanoparticles exit via port 42 after the last conductive ring 28i and can be collected in a conventional manner.

The two sputter deposition systems 36 can be provided with an identical target material 40, for a uniform shell to the nanoparticles. Alternatively, different materials can be provided to allow for multiple shells and/or alloy shells depending on the relative positions of the or each sputter deposition systems relative the dwell zone. A set of sputter targets placed at identical locations along the dwell zone will produce alloy shells, whereas sputter targets spaced along the dwell zone will be able to produce successive shells.

It will of course be understood that many variations may be made to the above-described embodiment without departing from the scope of the present invention.

1. Apparatus for the processing of nanoparticles, comprising a source of charged, moving nanoparticles of a first material and a first size, apparatus for imposing a like potential in a region lying in the path of the nanoparticles, and a physical vapour deposition source of a second material directed toward the region, thereby to produce nanoparticles of a second and greater size being a composite of the first and second materials.

2. Apparatus according to claim 1 in which the apparatus for imposing a like potential comprises one or more conductive rings surrounding the path of the nanoparticles.

3. Apparatus according to claim 1 in which the like potential decreases from a maximum to a minimum in the direction of travel of the moving nanoparticles.

4. Apparatus according to claim 3 in which the apparatus for imposing a like potential comprises one or more conductive rings surrounding the path of the nanoparticles and in which there are a plurality of conductive rings along the path of the nanoparticles, each at a successively lower potential.

5. Apparatus according to claim 4 in which each of the conductive rings is connected to a neighbouring ring by an electrically resistive element.

6. Apparatus according to claim 5 in which a first conductive ring is connected to a voltage source.

7. Apparatus according to claim 6 in which a last conductive ring is connected to an earth.

8. Apparatus according to claim 1 in which the moving nanoparticles are negatively charged and the imposed potential is negative.

9. Apparatus according to claim 1 in which the physical vapour deposition source is a sputter target.

10. Apparatus according to claim 1 in which the physical vapour deposition source is an evaporative source.

11. Apparatus according to claim 1 in which there is a plurality of physical vapour deposition sources.

12. Apparatus according to claim 11 in which all of the physical vapour deposition sources deposit the same material.

13. (canceled)
